(19) United States
(12) Patent Application Publication
(10) Pub. No.: US 2016/0169955 A1
(43) Pub. Date: Jun. 16, 2016

(54) ERROR DETECTION SYSTEM OF STORAGE DEVICE AND ERROR DETECTION METHOD THEREOF

(71) Applicant: Wistron Corporation, New Taipei City (TW)

(72) Inventors: Chia-Ming Tsai, New Taipei City (TW); Cheng-Kuang Hsieh, New Taipei City (TW); Yu-Hung Liu, New Taipei City (TW); Yuan-Hao Peng, New Taipei City (TW)

(21) Appl. No.: 14/665,000

(22) Filed: Mar. 23, 2015

(30) Foreign Application Priority Data
Dec. 10, 2014 (TW) 103143172

(51) Int. Cl. G01R 31/04

(52) U.S. Cl. CPC G01R 31/043; G01R 31/041

(57) ABSTRACT

A detection system for storage device includes a case, one or more storage modules, one or more transmission cables, and one or more detection modules. The case defines one or more receiving slots and includes one or more position detectors. The position detector is installed adjacently to the receiving slot. The storage module is received by the receiving slot. The storage module includes a base board and a connecting module installed on the base board. The position detector generates a first error signal when the storage module is not correctly seated in the receiving slot. The transmission cable is coupled to the connecting module. The detection module is electrically connected to the transmission cable. The detection module generates a second error signal when the transmission cable is not correctly connected to the connecting module. Accordingly, service personnel can identify and resolve the errors quickly to enhance service efficiency.

### CROSS-REFERENCES TO RELATED APPLICATIONS

This non-provisional application claims priority under 35 U.S.C. §119(a) on Patent Application No. 103143172 filed in Taiwan, R.O.C. on 2014 Dec. 10, the entire contents of which are hereby incorporated by reference.

### BACKGROUND

1. Technical Field

The instant disclosure relates to a detection system and method thereof, in particular, for a storage device.

2. Related Art

With the advancement in technology, the amount of digital information to process also increases tremendously. Therefore, data storage spaces, such as hard drives, are getting progressively bigger. However, the storage space of any single hard drive has its limit, which gives rise to other alternatives, for examples, redundant array of independent disks (RAID), data center, and cloud storage, as ways for storing large digital data.

A common computer cabinet is typically furnished with a multiplicity of motherboards held in different racks. Each motherboard is installed with multiple hard drives, with each additional hard drive providing more storage space. Normally, when one of the hard drives malfunctions, the corresponding motherboard is pulled out to replace the bad hard drive. On the other hand, the motherboard itself will be replaced if any is not working properly.

In other words, the service personnel at the scene would often be forced to remove either hard drives or motherboards. These routine removal and installation actions tend to let motherboards not be properly seated, or cause loose cabling between motherboards and servers going unnoticed. Other surrounding cables could be jerked loose unintentionally as well. In addition, for a data center that stores large amount of information, the computer cabinet would carry a heap of motherboards and hard drives. Such scenario creates great difficulties for the service personnel, who are tasked to locate any misseated motherboard or loose cable. Therefore, a resolution is needed to address the above-described issues.

### SUMMARY

In view of the foregoing, the instant disclosure provides a detection system, for conveniently inspect each storage media or unit of the storage device for improper installation or loose cabling, in order to give warning and request field service.

To achieve the above-mentioned capabilities, the detection system of the instant disclosure comprises a case, at least one storage module, at least one transmission cable, and at least one detection module. The case defines at least one receiving slot and includes a position detector, which is adjacent to one side of the receiving slot. The storage module, which is disposed in the receiving slot, includes a base board and a connecting module. The connecting module is arranged on the base board and has a pair of pins. The position detector detects whether the storage module is correctly installed in the receiving slot. If not, a first error signal will be generated. The transmission cable, which is plugged to the connecting module, includes a pair of signal wires coupled to respective pins. The detection module is electrically connected to the transmission cable, to determine whether the signal wires are correctly connected electrically to respective pins. A second error signal will be generated if a bad connection is detected.

Based on the disclosed system, if the base board is not correctly seated in the receiving slot, or the transmission cable is not properly wired to the connecting module, the system will issue the first and second error signals, respectively. Thereby, the service personnel can quickly identify the origin of the first or second error signal, then change out the storage module or inspect the transmission cable. Thus, field service can be done in less time to enhance service efficiency.

### BRIEF DESCRIPTION OF THE DRAWINGS

FIG. 1 is a perspective view of a storage device for an embodiment of the instant disclosure.

FIG. 2 is an exploded view of the device in FIG. 1.

FIG. 3 is a top view of the device in FIG. 1.

FIG. 4 is a schematic view showing a pair of pins for a connecting module of the device in FIG. 1.

FIG. 5 is a flowchart showing a detection method for a detection system of the instant disclosure.

FIG. 6 is a flowchart showing a variant of the detection method in FIG. 5.

### DETAILED DESCRIPTION

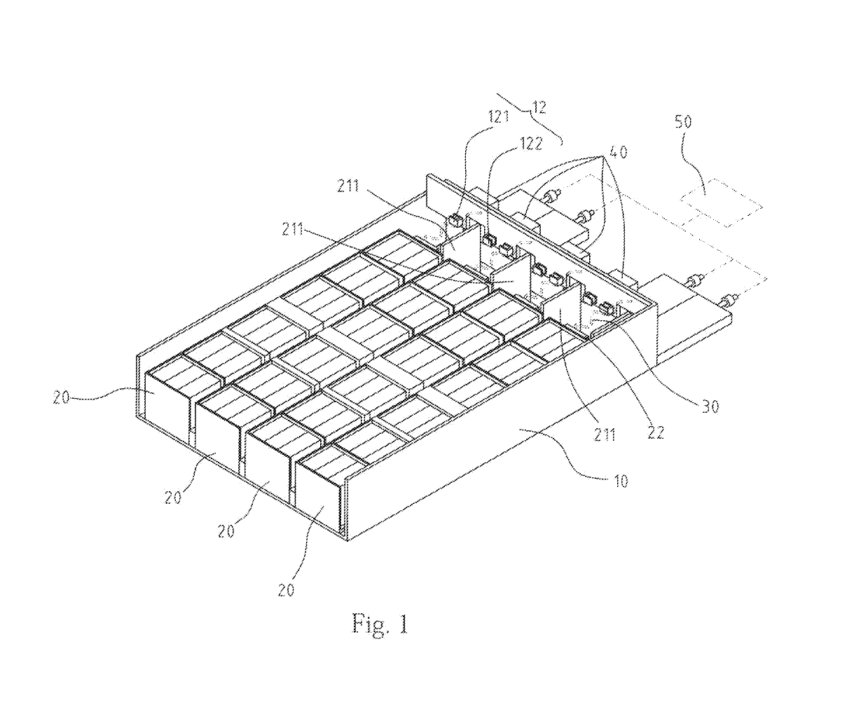

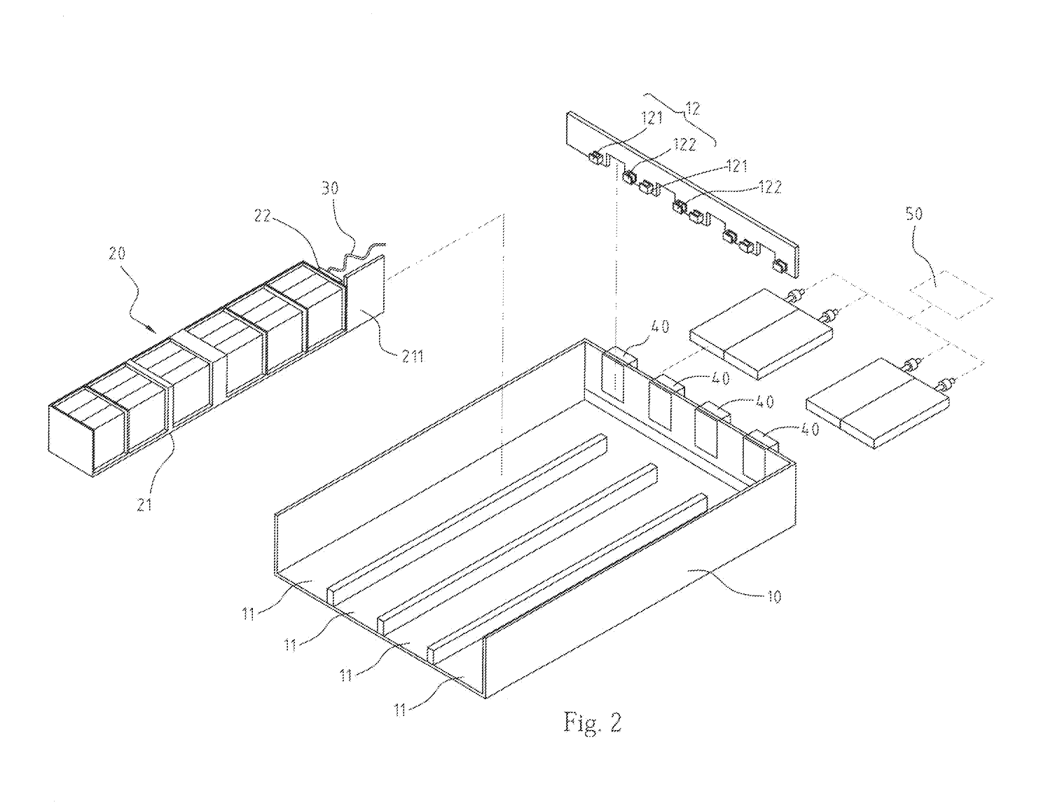

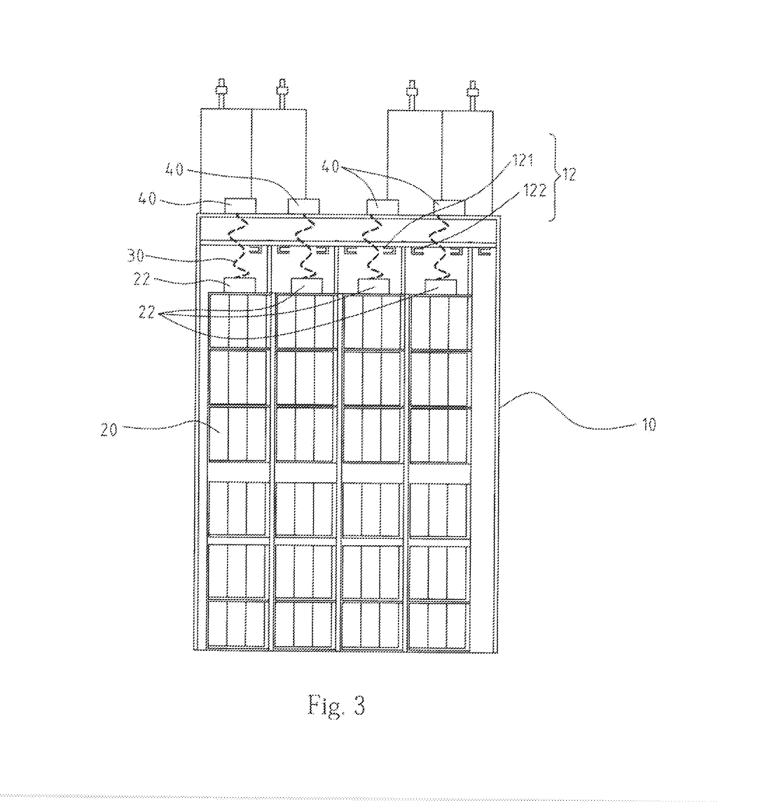

For the instant disclosure, FIG. 1 shows a perspective view of a data storage device for one embodiment, and FIG. 2 is an exploded view thereof. FIG. 3 is a top view of the same. Please refer to FIGS. 1 and 2, with the storage device comprises a case 10, a plurality of storage modules 20, a plurality of transmission cables 30, and a plurality of detection modules 40. Each storage module 20, with one side thereof connected to one of the transmission cables 30, is disposed in the case 10.

In conjunction with FIG. 3, the case 10 is formed with at least one receiving slot 11 and has at least one position detector 12. The position detector 12 is disposed adjacently to one side of the receiving slot 11. For the instant embodiment, the position detector is adjacent to one end of the receiving slot 11, but is not restricted thereto. For another embodiment, the position detector 12 can be arranged adjacently to the mouth or side portion that defines the receiving slot 11.

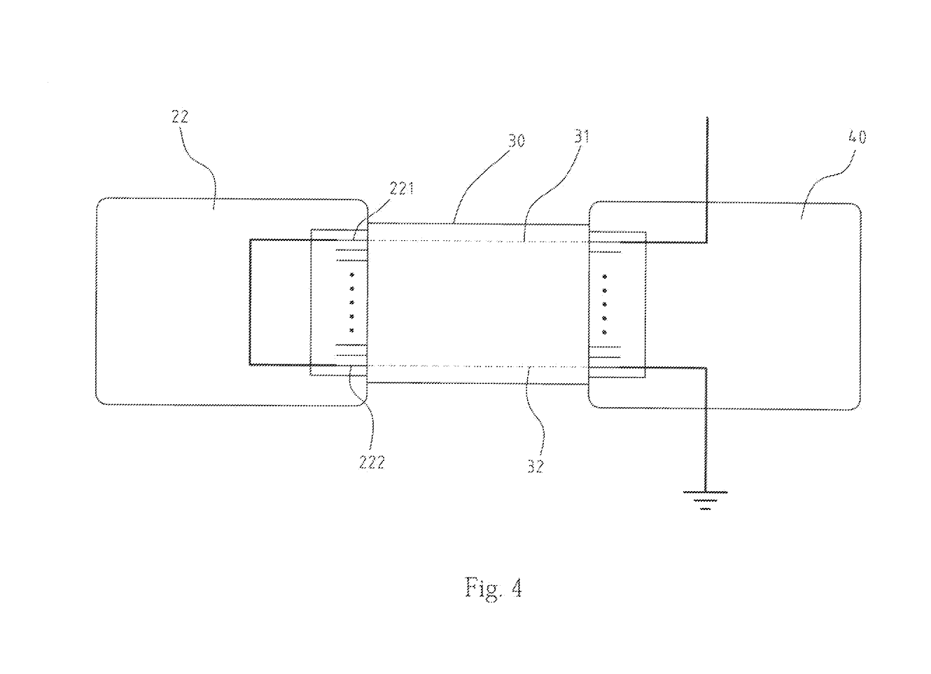

Turning now to FIG. 4, which illustrates a pair of pins 221 and 222 for a connecting module 22 of the instant disclosure. Based on FIGS. 1-4, each storage module 20 is disposed in one of the receiving slots 11, and includes a base board 21 and the connecting module 22. The connecting module 22 is arranged on the base board 21 and includes of the pins 221 and 222 (as shown in FIG. 4). Furthermore, each storage module 20 includes at least one storage medium, which could be a hard drive, a flash memory, or other storage medium capable of storing data, and is not limited thereto.

For the instant embodiment, with reference to FIGS. 1 and 3, each base board 21 further has a blocking portion 211 (as shown in FIG. 1). The blocking portion 211 can be in line with one of the position detectors 12, when the corresponding storage module 20 is disposed in the receiving slot 11. In other words, each position detector 12 detects whether the base board 21 of the corresponding storage module 20 is seated correctly in the receiving slot 11. If not, the position detector 12 will generate a first error signal.

Each position detector 12 includes an emitting unit 121 and a receiving unit 122. When the base board 21 is correctly seated, the blocking portion 211 acts as an interrupter to keep the positioning signal emitted by the emitting unit 121 from reaching the receiving unit 122. However, if the emitting unit 121 and the receiving unit 122 are not blocked off therebetween by the blocking portion 211, the position detector 12 will generate the first error signal.

Each position detector 12 may be a light sensor, a magnetic sensor, a limit switch, or a combination thereof. Thus, each storage module 20 may have a light-shielding portion, a magnetic sensing portion, a limiting portion, or a combination thereof, and is not limited thereto.

Each transmission cable 30, plugged to the connecting module 22 of one of the storage modules 20, has two signal wires 31 and 32 coupled to the pins 221 and 222, respectively. For the instant embodiment, each transmission cable 30 is plugged to the connecting module 22 of one of the base boards 21, such that the signal wires 31 and 32 are connected directly to the pins 221 and 222, respectively.

Each detection module 40 is electrically connected by the one of the transmission cables 30. The detection module 40 detects whether the signal wires 31 and 32 are electrically connected correctly to the pins 221 and 222. If the signal wires 31 and 32 are electrically connected incorrectly, the detection module 40 will generate a second error signal. In other words, when the transmission cable 30 is not correctly plugged to the connecting module 22 (such as floatingly connected or connected to one pin only), the detection module 40 will generate the second error signal.

More specifically, the detection module 40 detects the voltage levels of the signal wires 31 and 32. When the voltage level of any signal wire 31 or 32 is less than a predetermined value, the condition indicates the transmission cable 30 is not correctly plugged to the connecting module 22. As a result, the detection module 40 will generate the second error signal. It should be noted that the instant embodiment is offered for illustrative and exemplary purposes only, and it is not intended to limit the scope of the instant disclosure. Via the connecting module 22, the signal wires 31 and 32 form a loop circuit. That is, the pins 221 and 222 can electrically communicate with each other. Thus, when the signal wires 31 and 32 are connected to the pins 221 and 222, respectively, the preceding loop circuit is obtained. In other words, the detection module 40 is configured to detect whether the signal wires 31 and 32 have the same voltage levels that are substantially equal to or greater than the predetermined value, in order to determine if the transmission cable 30 is correctly connected to the connecting module 22. If the above condition is met, the transmission cable 30 is determined to be correctly connected to the connecting module 22. Conversely, for the case that the signal wires 31 and 32 have different voltage levels and both less than the predetermined value, the loop circuit defined by the signal wires 31 and 32 is said to be broken, which suggests the transmission cable 30 is not correctly connected to the connecting module 22. For such case, the detection module 40 will generate the second error signal.

Please refer back to FIG. 2. The storage device of the instant disclosure further includes a detection server 50. The detection server 50 is in communication with each of the position detectors 12 and the detection modules 40. When the detection server 50 receives the first error signal, the second error signal, or a combination thereof, a resulting warning signal will be generated. More specifically, when the detection server 50 receives the first error signal, a position error signal will be issued. Upon receiving the second error signal, a transmission cable error signal will be outputted. When the detection server 50 receives the first and second error signals simultaneously, the position and transmission cable error signals will be issued at the same time. If neither first error signal nor second error signal is received, the detection server 50 will give a normal signal indication. Thereby, the monitoring computers in connection with the detection server 50 can quickly sort out the abnormalities of the storage device, based on the position or the transmission cable error signal. Service personnel will then be dispatched on-site to correct the position of any misplaced storage module 20 or inspect the transmission cable 30.

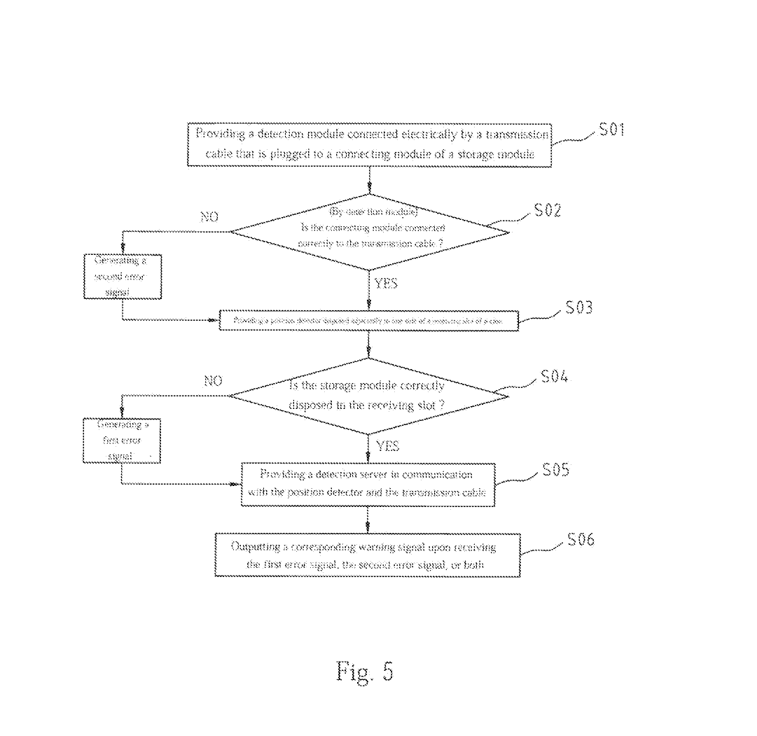

Turning now to FIG. 5, which illustrates a detection method of one embodiment employed by the detection system of the instant disclosure. The detection method is implemented by the above-described elements of the instant disclosure. For step S01, the detection module 40 is provided, which is electrically connected to the transmission cable 30. The transmission cable 30, which has a pair of signal wires 31 and 32, is plugged to the connecting module 22 of the storage module 20. The connecting module 22 includes pins 221 and 222 designated for coupling to the signal wires 31 and 32. Next, in step S02, the detection module 40 generates the second error signal upon detecting the signal wires 31 and 32 are not correctly connected to the pins 221 and 222.

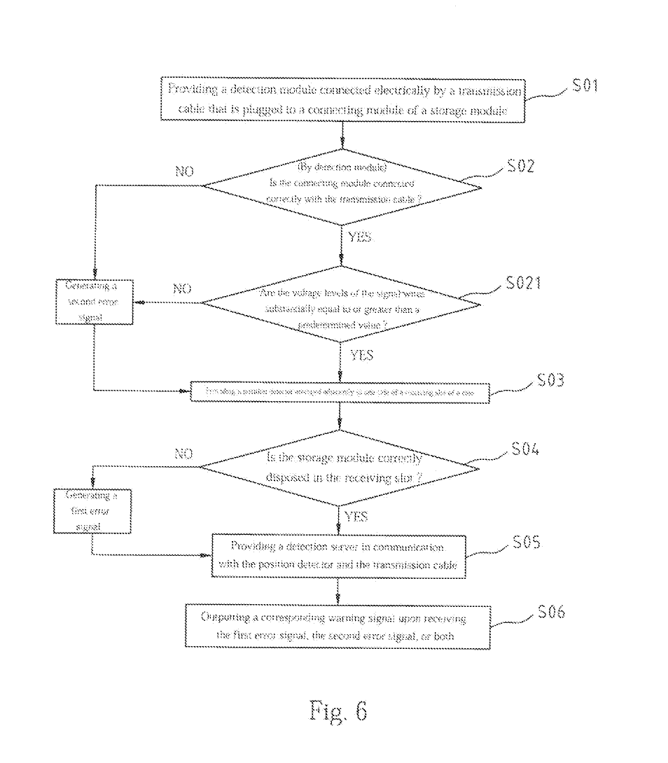

A variant of the above-described detecting method is illustrated by FIG. 6 for the detecting system of the instant disclosure. As shown in FIG. 6, step S02 further includes step S021. Step S021 involves detecting whether the voltage levels of the signal wires 31 and 32 are substantially equal to or greater than the predetermined value, and generating the second error signal if the voltage levels are substantially less than the predetermined value.

In addition, for step S02, after the detection module 40 has confirmed the signal wires 31 and 32 and the pins 221 and 222 are correctly connected, a proper connection signal is generated for receival by the detection server 50, before progressing to step S03.

In step S03, the position detector 12 is provided, which is disposed on the case 10 adjacent to one end of the receiving slot 11. For step S04, the first error signal is generated when the position detector 12 detects that the storage module 20 is not correctly seated in the receiving slot 11.

In addition, for step S04, when the position detector 12 detects that the storage module 20 is correctly seated in the receiving slot 11, a normal positioning signal is issued for receival by the detection server 50.

For the subsequent step S05, the detection server 50 is provided, which is in communication with the position detector 12 and the transmission cable 30. Finally, in step S06, the detection server 50 generates a corresponding warning signal upon receiving the first error signal, the second error signal, or the combination thereof.

Based on the preceding steps of both detecting methods, when the storage module 20 is not correctly seated in the receiving slot 11, the first error signal is generated. When the signal wires 31 and 32 are not correctly connected to the pins 221 and 222, the second error signal is generated. Therefore, based on the first or the second error signal, the service personnel can quickly tell if the problem of the storage device lies with the storage module 20 or the transmission cable 30. Thus, troubleshooting process can be sped up to increase service efficiency.

For an alternative detection method, which is also carried out by the same elements, the sole difference being steps S01 and S02 are reversed sequentially with steps S03 and S04. That is, for this other embodiment, steps S03 and S04 are implemented first, followed by steps S01 and S02. In other words, there is no required sequential order for executing the steps of the detection method of the instant disclosure. The sequence of the steps is not restricted for the instant disclosure.

Based on the above-described detection methods, the service personnel can quickly identify and resolve the abnormalities, thus enhancing service efficiency.

While the instant disclosure has been described by way of example and in terms of the preferred embodiments, it is to be understood that the invention needs not be limited to the disclosed embodiments. For anyone skilled in the art, various modifications and improvements within the spirit of the instant disclosure are covered under the scope of the instant disclosure. The covered scope of the instant disclosure is based on the appended claims.

What is claimed is:

1. A detection system for a storage device, the detection system comprising:
a case defining at least one receiving slot and comprising at least one position detector, the at least one position detector being adjacent to one side of the at least one receiving slot;
at least one storage module disposed in the at least one receiving slot, the at least one storage module including a base board and a connecting module disposed on the base board, the connecting module having a pair of pins, wherein the at least one position detector detects whether the at least one storage module is correctly disposed in the at least one receiving slot, and wherein a first error signal is generated if the at least one storage module is not correctly received by the at least one receiving slot;
at least one transmission cable plugged to the connecting module, the at least one transmission cable having a pair of signal wires for coupling to the pins; and
at least one detection module electrically connected to the at least one transmission cable, wherein the at least one detection module detects whether the signal wires are electrically connected correctly to the pins, and wherein a second error signal is generated if the signal wires are electrically connected incorrectly to the pins.

2. The detection system of a storage device of claim 1, further comprising a detection server in communication with the at least one position detector and the at least one detection module, wherein when the first error signal, the second error signal, or both is received by the detection server, the detection server is capable of generating a corresponding warning signal.

3. The detection system of a storage device of claim 1, wherein the at least one position detector includes an emitting unit and a receiving unit, wherein the base board has a blocking portion, and wherein when the emitting unit emits a positioning signal free of interruption by the blocking portion to the receiving unit, the at least one position detector generates the first error signal.

4. The detection system of a storage device of claim 3, wherein the at least one position detector is a light sensor, a magnetic sensor, a limit switch, or a combination thereof.

5. The detection system of a storage device of claim 1, wherein the at least one detection module detects the voltage levels of the signal wires, and wherein the at least one detection module generates the second error signal when one or more voltage levels are substantially less than a predetermined value.

6. A detection method for a storage device, the detection method comprising:
providing at least one detection module electrically connected to at least one transmission cable, the at least one transmission cable having a pair of signal wires being plugged to a connecting module of at least one storage module, the connecting module having a pair of pins for coupling to the signal wires; and
generating a second error signal when the signal wires being coupled incorrectly to the pins.

7. The detection method for a storage device of claim 6, further comprising:
providing at least one position detector disposed adjacently to at least one receiving slot defined by a case; and
generating a first error signal when the at least one storage module being incorrectly received by the at least one receiving slot.

8. The detection method for a storage device of claim 6, wherein the at least one detection module detects the voltage levels of the signal wires, and wherein the at least one detection module generates the second error signal when any of the voltage levels is substantially less than a predetermined value.

9. The detection method for a storage device of claim 7, wherein the at least one detection module detects the voltage levels of the signal wires, and wherein the at least one detection module generates the second error signal when any of the voltage levels is substantially less than a predetermined value.

10. The detection method for a storage device of claim 7, further comprising:
providing a detection server in communication with the at least one position detector and the at least one transmission cable,
wherein when the first error signal, the second error signal, or both is received by the detection server, the detection server is capable of generating a corresponding warning signal.

11. A detection method for a storage device, the detection method comprising:
providing at least one storage module and at least one position detector, wherein the at least one storage module is received by at least one receiving slot defined by a case, and wherein the at least one position detector is disposed adjacently to one side of the at least one receiving slot; and
generating a first error signal, when the at least one position detector detects the at least one storage module being incorrectly received by the at least one receiving slot.

12. The detection method for a storage device of claim 11, further comprising:
providing at least one detection module, wherein the at least one detection module is electrically connected to at least one transmission cable having a pair of signal wires, wherein the at least one transmission cable is plugged to a connecting module of the at least one storage module, and wherein the connecting module has a pair of pins for coupling to the signal wires; and
generating a second error signal by the at least one detection module, when the at least one detection module detects the signal wires being incorrectly coupled to the pins.

13. The detection method for a storage device of claim 12, wherein for the step of generating the second error signal, when the at least one detection module detects any of the voltage levels is substantially less than a predetermined value, the second error signal is generated by the at least one detection module.

14. The detection method of claim 12, further comprising:
providing a detection server in communication with the at least one position detector and the at least one transmission cable; and
outputting a corresponding warning signal by the detection server, when the detection server receives the first error signal, the second error signal, or both.
